(19) United States
(12) Patent Application Publication
(10) Pub. No.: US 2025/0072112 A1
(43) Pub. Date: Feb. 27, 2025

(54) DISPLAY PANEL AND DISPLAY DEVICE

(71) Applicant: Wuhan China Star Optoelectronics Semiconductor Display Technology Co., Ltd., Wuhan (CN)

(72) Inventor: Dan BAI, Wuhan (CN)

(21) Appl. No.: 17/777,037

(22) PCT Filed: Apr. 19, 2022
(86) PCT No.: PCT/CN2022/087668

§ 371 Date: Nov. 16, 2024

(30) Foreign Application Priority Data
Mar. 23, 2022 (CN) 202210304793.0

(51) Int. Cl. H01L 27/12

(52) U.S. Cl. CPC H01L 27/1218; H01L 27/124

(57) ABSTRACT

A display panel and a display device are provided. The display panel includes a substrate, a ladder structure, and an electrode layer disposed in a stack. The ladder structure is located in an encapsulation region. The ladder structure includes a first film layer and a second film layer disposed in a stack. An undercut opening is defined on a lateral side of the first film layer. The second film layer includes a first sub-layer and a second sub-layer disposed in a stack. A thickness of the second sub-layer is greater than a thickness of the first sub-layer. The first sub-layer is a metal film layer. The second sub-layer is an organic film layer.

### FIELD OF INVENTION

The present application relates to a field of display technologies, and particularly relates to a display panel and a display device.

### BACKGROUND

With development of display technology, low temperature polycrystalline oxides (LTPOs), which act as a low power consumption display technology, has received more and more attention. Compared to low-temperature polycrystalline-silicon thin film transistors (LTPS TFTs), low-temperature polycrystalline-oxide thin film transistors (LTPO TFTs) have lower driving power.

Currently, in structures of LTPO display panels, in order to block water and oxygen from intruding, a special structure is formed at some positions of the LTPO display panels, which can make organic electrode layers be discontinuous at the special positions but thin film encapsulation structures be continuous. For example, the LTPO display panels include display regions and peripheral regions adjacent to the display regions. In the peripheral regions, inorganic layer structures include undercut openings with openings. Organic electrode layers are arranged on the inorganic layer structures and are cut off on the undercut openings of the inorganic layer structures to block moisture and/or oxygen from intruding into the LTPO display panels from the organic electrode layers to affect reliability of products. However, because the undercut openings are defined in the inorganic layer structures, which manufacturing steps are complicated. In this way, production capacity can be reduced and manufacturing cost is increased.

As illustrated in FIG. 1 and FIG. 2, a display panel includes a display region 1000, a functional region 2000, and an encapsulation region 3000 located between the display region 1000 and the functional region 2000. In the encapsulation region 3000, the display panel includes a ladder structure 132. In the prior art, generally, an undercut opening 1320 is formed on a lateral side of the ladder structure 132, an electrode layer 170 is disposed on the ladder structure 132, and the electrode layer 170 is cut off at the undercut opening 1320 of the ladder structure 132, thereby blocking moisture and/or oxygen from intruding into a display panel, while production capacity is able to be improved to reduce manufacturing cost of the display panel. However, the ladder structure 132 is generally a metal structure. The ladder structure 132 includes a third film layer 1323, a first film layer 1321, and a second film layer 1322 disposed in a stack. Wherein, a material of the third film layer 1323 and a material of the second film layer 1322 are both a metal of titanium, and a material of the first film layer 1321 is a metal of aluminum. In a conventional metal undercut (UC) process, the undercut opening 1320 is formed in the ladder structure 132 by side etching in the first film layer 1321. However, because a thickness of the second film layer 1322 is relatively thin (generally dozens of nanometers), the second film layer 1322 is easily affected by subsequent processes (e.g., defining an opening in the functional region 2000) of the display panel and collapses, thereby causing damage to the undercut openings 1320. Therefore, the electrode layer 170 located on the ladder structure 132 cannot be cut off at the undercut opening 1320, which finally causes moisture and/or oxygen to penetrate into a display device from outside of the organic electrode layer and affects reliability of products.

### SUMMARY OF INVENTION

### Technical Solutions

Embodiments of the present application provides a display panel and a display device to ease insufficiency in the related art.

### Solutions to Technical Problem

In order to realize the aforesaid function, technical solutions provided by embodiments of the present application are as follows.

One embodiment of the present application provides a display panel, including a display region, a functional region, and an encapsulation region located between the display region and the functional region.

The display panel includes:
a substrate;
a ladder structure disposed on the substrate and located in the encapsulation region, wherein an undercut opening is defined on a lateral side of the ladder structure, the ladder structure at least includes a first film layer and a second film layer disposed in a stack, the undercut opening is defined on a lateral side of the first film layer, and an orthogonal projection of the second film layer on the substrate covers an orthogonal projection of the first film layer on the substrate; and
an electrode layer disposed on the ladder structure and the substrate, wherein the electrode layer is cut off at a position where the undercut opening is; and
wherein the second film layer includes a first sub-layer and a second sub-layer disposed in a stack on a side of the first film layer away from the substrate, a thickness of the second sub-layer is greater than a thickness of the first sub-layer, the first sub-layer is a metal film layer, and the second sub-layer is an organic film layer.

In the display panel provided by one embodiment of the present application, the display panel includes a first insulation functional layer located between the substrate and the ladder structure;
the ladder structure includes a plurality of ladder sub-sections spaced apart in the encapsulation region, the undercut opening is defined on a lateral side of each of the ladder sub-sections; and
wherein the electrode layer includes a first electrode layer located on a plurality of the ladder sub-sections, and a second electrode layer located on the first insulation functional layer.

In the display panel provided by one embodiment of the present application, the display panel includes a plurality of channels spaced apart and located in the encapsulation region, and the channels include via holes penetrating through the first insulation functional layer; and
wherein orthogonal projections of the ladder sub-sections on the substrate do not overlap with orthogonal projections of the channels on the substrate.

In the display panel provided by one embodiment of the present application, the encapsulation region includes a first encapsulation sub-region, a second sub-region, and a spacer region located between the first encapsulation sub-region and the second sub-region, the first encapsulation region is close to the functional region, and the second encapsulation region is close to the display region;
the ladder structure includes a plurality of first ladder sub-sections disposed in the first encapsulation sub-region, and a plurality of second ladder sub-sections spaced apart in the second encapsulation sub-region;
the channels are located in the second encapsulation region, and the orthogonal projections of the channels on the substrate do not overlap with orthogonal projections of the second ladder sub-sections on the substrate.

In the display panel provided by one embodiment of the present application, the orthogonal projections of the second ladder sub-sections on the substrate are located between orthogonal projections of two adjacent channels on the substrate.

In the display panel provided by one embodiment of the present application, the display panel includes a thin film transistor layer disposed on the substrate and an insulation layer disposed on the thin film transistor layer, and the insulation layer includes a second insulation functional layer located in the display region and the second sub-layer located in the encapsulation region.

In the display panel provided by one embodiment of the present application, the second insulation functional layer includes a planarization layer located in the display region and disposed on the thin film transistor layer, and a material of the second sub-layer is same as a material of the planarization layer.

In the display panel provided by one embodiment of the present application, a thickness of the second sub-layer is greater than or equal to a thickness of the planarization layer.

In the display panel provided by one embodiment of the present application, the thin film transistor layer includes a metal layer located between the substrate and the insulation layer, and the metal layer includes the ladder structure;
wherein the ladder structure includes a third film layer, the first film layer, and the second film layer disposed in a stack; and wherein a material of the third film layer, a material of the first film layer, and a material of the first film layer are metal metals, and a material of the second sub-layer is an organic insulation material.

In the display panel provided by one embodiment of the present application, an orthogonal projection of the third film layer on the substrate overlaps with an orthogonal projection of the second film layer on the substrate.

In a display device provided by one embodiment of the present application, the display device includes a display panel. The display panel includes:
a display region, a functional region, and an encapsulation region located between the display region and the functional region;
The display panel includes:
a substrate;
a ladder structure disposed on the substrate and located in the encapsulation region, wherein an undercut opening is defined on a lateral side of the ladder structure, the ladder structure at least includes a first film layer and a second film layer disposed in a stack, the undercut opening is defined on a lateral side of the first film layer, and an orthogonal projection of the second film layer on the substrate covers an orthogonal projection of the first film layer on the substrate; and
an electrode layer disposed on the ladder structure and the substrate, wherein the electrode layer is cut off at a position where the undercut opening is; and
wherein the second film layer includes a first sub-layer and a second sub-layer disposed in a stack on a side of the first film layer away from the substrate, a thickness of the second sub-layer is greater than a thickness of the first sub-layer, the first sub-layer is a metal film layer, and the second sub-layer is an organic film layer.

In the display device provided by one embodiment of the present application, the display panel includes a first insulation functional layer located between the substrate and the ladder structure;
the ladder structure includes a plurality of ladder sub-sections spaced apart in the encapsulation region, the undercut opening is defined on a lateral side of each of the ladder sub-sections; and
wherein the electrode layer includes a first electrode layer located on a plurality of the ladder sub-sections, and a second electrode layer located on the first insulation functional layer.

In the display device provided by one embodiment of the present application, the display panel includes a plurality of channels spaced apart and located in the encapsulation region, and the channels include via holes penetrating through the first insulation functional layer; and
wherein orthogonal projections of the ladder sub-sections on the substrate do not overlap with orthogonal projections of the channels on the substrate.

In the display device provided by one embodiment of the present application, the encapsulation region includes a first encapsulation sub-region, a second sub-region, and a spacer region located between the first encapsulation sub-region and the second sub-region, the first encapsulation region is close to the functional region, and the second encapsulation region is close to the display region;
the ladder structure includes a plurality of first ladder sub-sections disposed in the first encapsulation sub-region, and a plurality of second ladder sub-sections spaced apart in the second encapsulation sub-region;
the channels are located in the second encapsulation region, and the orthogonal projections of the channels on the substrate do not overlap with orthogonal projections of the second ladder sub-sections on the substrate.

In the display device provided by one embodiment of the present application, the orthogonal projections of the second ladder sub-sections on the substrate are located between orthogonal projections of two adjacent channels on the substrate.

In the display device provided by one embodiment of the present application, the display panel includes a thin film transistor layer disposed on the substrate and an insulation layer disposed on the thin film transistor layer, and the insulation layer includes a second insulation functional layer located in the display region and the second sub-layer located in the encapsulation region.

In the display device provided by one embodiment of the present application, the second insulation functional layer includes a planarization layer located in the display region and disposed on the thin film transistor layer, and a material of the second sub-layer is same as a material of the planarization layer.

In the display device provided by one embodiment of the present application, a thickness of the second sub-layer is greater than or equal to a thickness of the planarization layer.

In the display device provided by one embodiment of the present application, the thin film transistor layer includes a metal layer located between the substrate and the insulation layer, and the metal layer includes the ladder structure;
wherein the ladder structure includes a third film layer, the first film layer, and the second film layer disposed in a stack; and wherein a material of the third film layer, a material of the first film layer, and a material of the first film layer are metal metals, and a material of the second sub-layer is an organic insulation material.

In the display device provided by one embodiment of the present application, an orthogonal projection of the third film layer on the substrate overlaps with an orthogonal projection of the second film layer on the substrate.

### Benefits of Disclosure

### Benefits

The embodiments of the present application provide a display panel and a display device. The display panel includes a display region, a functional region, and an encapsulation region located between the display region and the functional region. The display panel includes: a substrate; a ladder structure disposed on the substrate and located in the encapsulation region, the ladder structure at least includes a first film layer and a second film layer disposed in a stack, wherein an undercut opening is defined on a lateral side of the first film layer, and an orthogonal projection of the second film layer on the substrate covers an orthogonal projection of the first film layer on the substrate; and an electrode layer disposed on the ladder structure and the substrate, wherein the electrode layer is cut off at a position where the undercut opening is. In the embodiments of the present application, by disposing the second film layer including a first sub-layer and a second sub-layer disposed in a stack on a side of the first film layer away from the substrate, by configuring a thickness of the second sub-layer to be greater than a thickness of the first sub-layer, by configuring the first sub-layer to be a metal film layer, and by configuring the second sub-layer to be an organic film layer, thereby serving a protection effect to the first sub-layer and preventing poor phenomena such as collapse, etc. from appearing in the first sub-layer in the manufacturing processes of the display panel. These poor phenomena can lead to diffusion of water and oxygen from the encapsulation region to the display region and affecting reliability of the display device.

### DESCRIPTION OF DRAWINGS

The technical solutions and other advantageous effects of the present invention will be apparent with reference to the following accompanying drawings and detailed description of embodiments of the present disclosure.

FIG. 1 is a sectional schematic diagram of a current display panel.

FIG. 2 is a diagram of an enlargement of position A in FIG. 1.

FIG. 3 is a sectional schematic diagram of a display panel provided by one embodiment of the present application.

FIG. 4 is a diagram of an enlargement of position B in FIG. 3.

FIG. 5 is a flowchart of a manufacturing method of the display panel provided by one embodiment of the present application.

FIG. 6A to FIG. 6F are flowcharts of manufacturing processes of structures of the display panel in FIG. 5.

### EMBODIMENTS OF DISCLOSURE

### Detailed Description of Embodiments

Embodiments of the present application provide a display panel and a display device. For making the purposes, technical solutions and effects of the present application be clearer and more definite, the present application will be further described in detail below. It should be understood that the specific embodiments described herein are merely for explaining the present application and are not intended to limit the present application.

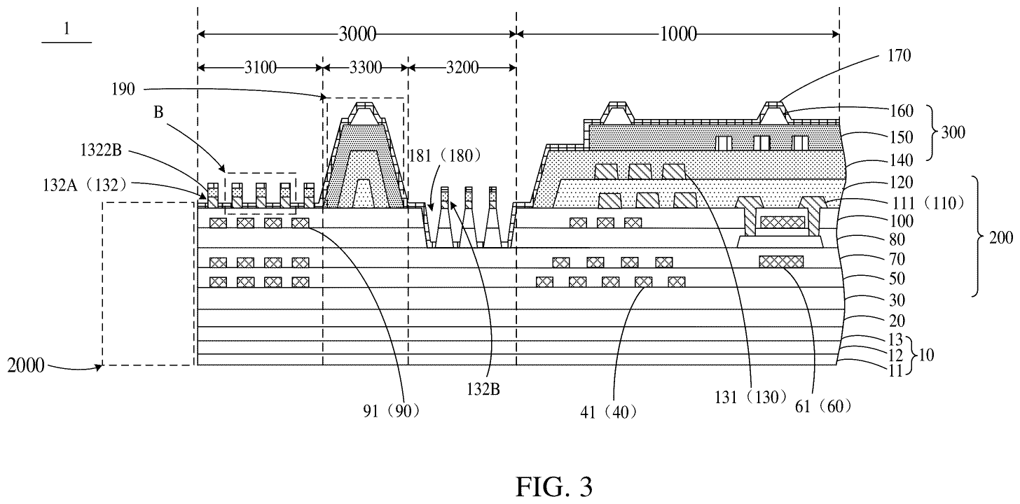

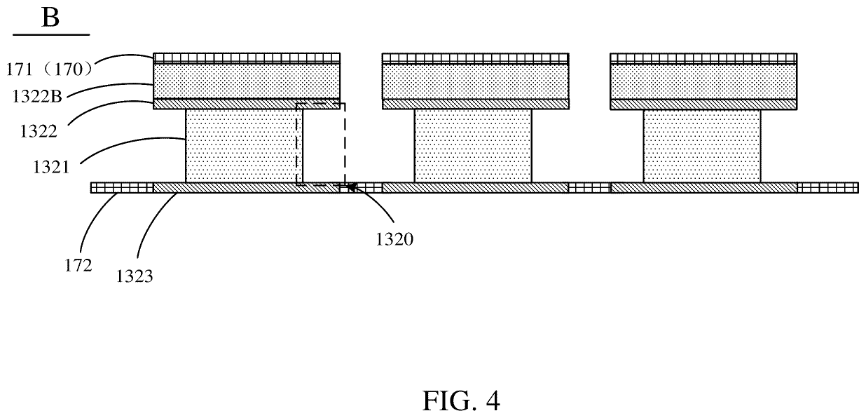

Please refer to FIG. 3 to FIG. 4. This embodiment provide a display panel 1, including a display region 1000, a functional region 2000, and an encapsulation region 3000 located between the display region 1000 and the functional region 2000. The display panel 1 includes:
a substrate 10;
a ladder structure 132 disposed on the substrate 10 and located in the encapsulation region 3000, wherein an undercut opening 1320 is defined on a lateral side of the ladder structure 132, the ladder structure 132 at least includes a first film layer 1321 and a second film layer 1322 disposed in a stack, the undercut opening 1320 is defined on a lateral side of the first film layer 1321, and an orthogonal projection of the second film layer 1322 on the substrate 10 covers an orthogonal projection of the first film layer 1321 on the substrate 10; and
an electrode layer 170 disposed on the ladder structure 132 and the substrate 10, wherein the electrode layer 170 is cut off at a position where the undercut opening 1320 is; and
wherein the second film layer 1322 includes a first sub-layer 1322A and a second sub-layer 1322B disposed in a stack on a side of the first film layer 1321 away from the substrate 10, a thickness of the second sub-layer 1322B is greater than a thickness of the first sub-layer 1322A, the first sub-layer 1322A is a metal film layer, and the second sub-layer 1322B is an organic film layer.

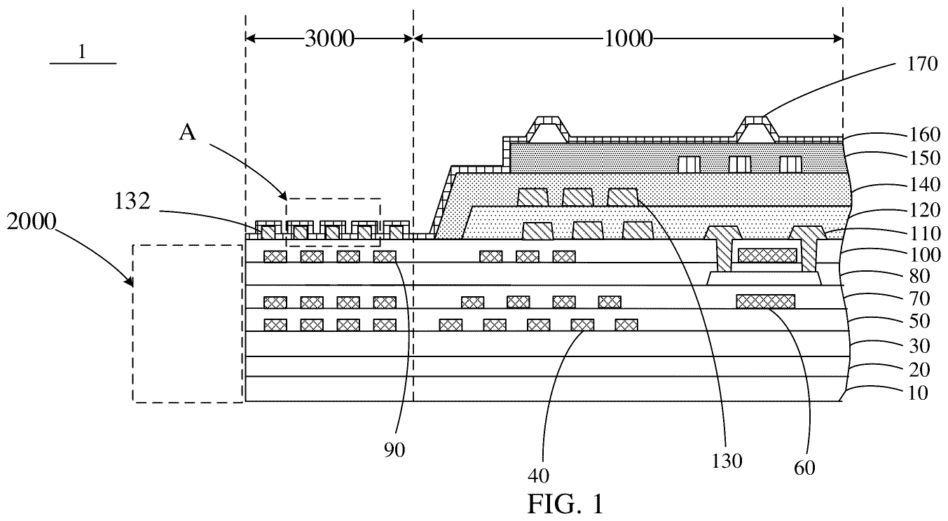

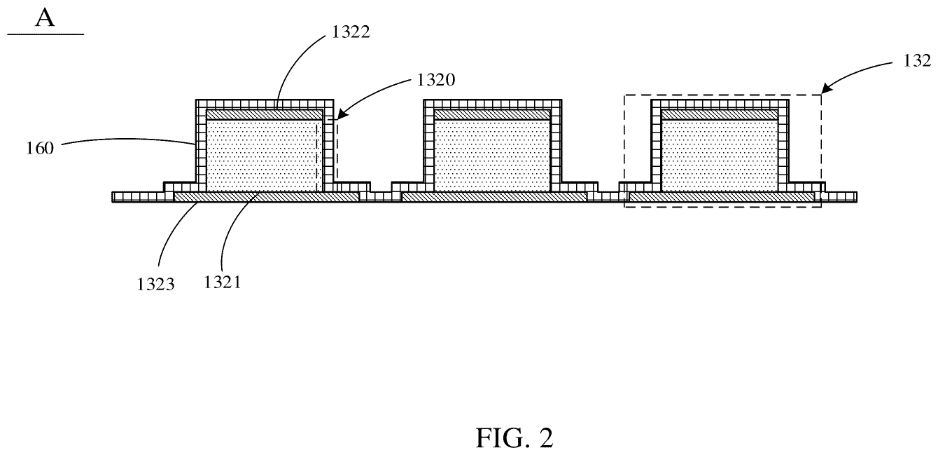

It can be understood that currently, in the current display panel 1, as illustrated in FIG. 1 and FIG. 2, wherein FIG. 1 is a sectional schematic diagram of a current display panel, and FIG. 2 is a diagram of an enlargement of position A in FIG. 1. The display panel 1 includes a display region 1000, a functional region 2000, and an encapsulation region 3000 located between the display region 1000 and the functional region 2000. In the encapsulation region 3000, the display panel 1 includes a ladder structure 132. In the prior art, generally, an undercut opening 1320 is defined on a lateral side of the ladder structure 132, an electrode layer 170 is disposed on the ladder structure 132, and the electrode layer 170 is cut off at the undercut opening 1320 of the ladder structure 132, thereby blocking moisture and/or oxygen from intruding into the display panel 1, while production capacity is able to be improved to reduce manufacturing cost of the display panel 1. However, please combine FIG. 1 and FIG. 2, wherein, FIG. 2 is a diagram of an enlargement of position A in FIG. 1; the ladder structure 132 is generally a metal structure, the ladder structure 132 includes a third film layer 1323, a first film layer 1321, and a second film layer 1322 disposed in a stack, and wherein, a material of the third film layer 1323 and a material of the second film layer 1322 are both a metal of titanium, and a material of the first film layer 1321 is a metal of aluminum. In a conventional metal undercut (UC) process, the undercut opening 1320 is formed in the ladder structure 132 by side etching in the first film layer 1321. However, because a thickness of the second film layer 1322 is relatively thin, the second film layer 1322 is easily affected by subsequent processes of the display panel and collapses. Therefore, the electrode layer 170 located on the ladder structure 132 cannot be cut off at the undercut opening 1320, which finally causes moisture and/or oxygen to penetrate into the display device from outside of the organic electrode layer 170 and affects reliability of products.

Continuing from the above, in this embodiment, in the ladder structure 132, by disposing the second film layer 1322 including a first sub-layer 1322A and a second sub-layer 1322B disposed in a stack on a side of the first film layer 1321 away from the substrate 10, by configuring a thickness of the second sub-layer 1322B to be greater than a thickness of the first sub-layer 1322A, by configuring the first sub-layer 1322A to be a metal film layer, and by configuring the second sub-layer 1322B to be an organic film layer, a protection effect is served to the first sub-layer 1322A, preventing poor phenomena such as collapse, etc. from appearing in the first sub-layer 1322A in manufacturing processes of the display panel 1. These poor phenomena can lead to diffusion of water and oxygen from the encapsulation region 3000 to the display region 1000 and affecting reliability of the display device.

In one embodiment, please combine FIG. 3 and FIG. 4. Wherein, FIG. 3 is a sectional schematic diagram of a display panel provided by one embodiment of the present application, and FIG. 4 is a diagram of an enlargement of position B in FIG. 3.

In this embodiment, the display panel 1 includes a display region 1000, a functional region 2000, and an encapsulation region 3000 located between the display region 1000 and the functional region 2000. The display panel 1 includes a substrate 10, a buffer layer 20, a thin film transistor layer 200, and an insulation layer 300 disposed in a stack. Wherein, the thin film transistor layer 200 includes a first thin film transistor (not shown in the figure) and a second thin film transistor (not marked in the figure) spaced apart. The first thin film transistor includes a polycrystalline silicon semiconductor layer (not shown in the figure) located on the substrate 10. The second thin film transistor includes an oxide semiconductor layer (not marked in the figure) located on the substrate 10. It can be understood that in this embodiment, a technical solution of the present application is described by taking the display panel 1 being an low-temperature polycrystalline-oxide (LTPO) display panel as an example.

The substrate 10 includes a first substrate 11, a inter layer 12, and a second substrate 13 sequentially disposed in a stack. Wherein the first substrate 11 and the second substrate 13 can both include rigid substrates or flexible substrates. When the first substrate 11 and the second substrate 13 are both the rigid substrates, their materials can be a metal or glass. When the first substrate 11 and the second substrate 13 are both the flexible substrates, their materials can include at least one of acrylic resin, methacrylic resin, polyisoprene, vinyl resin, epoxy-based resin, polyurethane-based resin, cellulose resin, siloxane resin, polyimide-based resin, or polyamide-based resin. A material of the inter layer 12 includes but is not limited to a material with water absorption properties such as silicon nitride (SiNx), silicon oxide (SiOx), etc. In this embodiment, the materials of the first substrate 11, the second substrate 13, and the inter layer 12 are not limited.

The thin film transistor layer 200 includes a first gate insulation layer 30, a first metal layer 40, a second gate insulation layer 50, a second metal layer 60, a first interlayer insulation layer 70, a third gate insulation layer 80, a third metal layer 90, a second interlayer insulation layer 100, a fourth metal layer 110, a first planarization layer 120, and a fifth metal layer 130 disposed in a stack on the substrate 10. Specifically, the first metal layer 40 includes a first gate electrode 41, the second metal layer 60 includes a second gate electrode 61, the third metal layer 90 includes a third gate electrode 91, the fourth metal layer 110 includes a first source-drain electrode 111, and the fifth metal layer 130 includes a second source-drain electrode 131.

Wherein, the first gate electrode 41, the second gate electrode 61, and the third gate electrode 91 can include low-resistance metal materials. For example, the aforesaid gate electrodes can include conductive materials having molybdenum (Mo), aluminum (Al), copper (Cu), and/or titanium (Ti), etc., and can include a single layer or a plurality of layers of the aforesaid materials.

The first source-drain electrode 111 and the second source-drain electrode 131 can include conductive materials. For example, materials of the first source-drain electrode 111 and the second source-drain electrode 131 can include conductive materials of molybdenum (Mo), aluminum (Al), copper (Cu), and/or titanium (Ti), etc., and can include a single layer or a plurality of layers of the aforesaid materials. It should be noted that, in this embodiment, the second source-drain electrode 131 including a multi-layer structure of titanium (Ti)/aluminum (Al)/titanium (Ti) is taken as an example to describe the technical solution of the present application.

The insulation layer 300 includes a first insulation functional layer (not marked in the figure) and a second insulation functional layer (not marked in the figure). The first insulation layer includes a third gate insulation layer 80 and a second interlayer insulation layer 100 disposed in a stack. The second insulation functional layer includes a second planarization layer 140, a pixel definition layer 150, and a spacer layer 160 disposed in a stack on the fifth metal layer 130. Wherein, the first planarization layer 120 and the second planarization layer 140 both include an organic insulation material. The pixel definition layer 150 includes an inorganic insulation material.

The display panel 1 further includes an opening (not shown in the figure) located in the functional region 2000. The opening can penetrate a plurality of film layers on/over the substrate 10, such as the buffer layer 20, the first gate insulation layer 30, the second gate insulation layer 50, the first interlayer insulation layer 70, the third gate insulation layer 80, the second interlayer insulation layer 100, and the first planarization layer 120, and can also penetrate the substrate 10, which are not specifically limited in this embodiment. The opening can have any one of various appropriate shapes, such as, a rectangle or an oval, and a number of the opening is not limited to one. It should be noted that, in this embodiment, the technical solution of the present application is described by taking a part of the film layers of the display panel 1 corresponding to the functional region 2000 used for cutting to form the opening as an example, and wherein the part of the cut film layer is not specifically limited.

The display panel 1 includes a ladder structure 132 disposed on the substrate 10 and located in the encapsulation region 3000. An undercut opening 1320 is defined on a lateral side of the ladder structure 132. The ladder structure 132 at least includes a first film layer 1321 and a second film layer 1322 disposed in a stack. The undercut opening 1320 is defined on a lateral side of the first film layer 1321. Specifically, the ladder structure 132 includes a third film layer 1323, a first film layer 1321, and a second film layer 1322 disposed in a stack and on the substrate 10. The undercut opening 1320 is defined on a lateral side of the first film layer 1321. An orthogonal projection of the second film layer 1322 on the substrate 10 covers an orthogonal projection of the first film layer 1321 on the substrate 10. An orthogonal projection of the third film layer 1323 on the substrate 10 overlaps with an orthogonal projection of the second film layer 1322 on the substrate 10.

A material of the ladder structure 132 includes metal. For example, the ladder structure 132 can include one material that is same as one of materials configured to form the first gate electrode 41, the second gate electrode 61, the third gate electrode 91, the first source-drain electrode 111, or the second source-drain electrode 131.

Furthermore, the fourth metal layer 110 includes the ladder structure 132. The ladder structure 132 and the second source-drain electrode 131 are made of a same material and are disposed in a same layer, i.e., the ladder structure 132 and the second source-drain electrode 131 can be manufactured in a same process. Therefore, manufacturing cost of the display panel 1 is reduced, and influence on the thickness of the display panel 1 is also minimized. Specifically, the third film layer 1323, the first film layer 1321, and the first film layer 1322 both include metal materials. Wherein, a material of the third film layer is titanium (Ti), a material of the first film layer 1321 is aluminum (Al), and a material of the second film layer 1322 includes titanium (Ti).

The display panel 1 includes the electrode layer 170 disposed on the ladder structure 132 and the base 10, and the electrode layer 170 is cut off at a position where the undercut opening 1320 is. Specifically, the first insulation functional layer is located between the substrate 10 and the ladder structure 132. The ladder structure 132 includes a plurality of ladder sub-sections spaced apart in the encapsulation region (not marked in the figure). The undercut opening 1320 is defined on a lateral side of each of the ladder sub-sections. Wherein, the plurality of ladder sub-sections are disposed enclosed the functional region 2000, and the electrode layer 170 includes a first electrode layer 171 located on the plurality of ladder sub-sections, and a second electrode layer 172 located on the first insulation functional layer, thereby blocking moisture and/or oxygen from intruding into the display panel 1 from the electrode layer 170 to affect product reliability.

It can be understood that when the second source-drain electrode 131 is a multi-layer structure of titanium (Ti)/aluminum (Al)/titanium (Ti), a thickness of the titanium metal ranges from 20 nanometers to 40 nanometers, and a thickness of the aluminum metal ranges 60 nanometers to 70 nanometers, i.e., in the ladder structure 132, a thickness of the second film layer 1322 ranges from 20 nanometers to 40 nanometers, a thickness of the first film layer 1321 ranges from 60 nanometers to 70 nanometers, and a thickness of the third film layer ranges from 20 nanometers to 40 nanometers. As the undercut opening 1320 is defined on the lateral side of the ladder structure 132, the undercut opening 1320 is defined on the lateral side of the first film layer 1321, as illustrate in FIG. 2, when the opening is defined in the display panel 1, the second film layer 1322, which has a smaller thickness and is not covered by any film layer, has a risk of collapse, thereby causing damage to the undercut opening 1320.

Continuing from the above, in this embodiment, the electrode layer 170 of the display panel is deposited on a entire surface. Therefore, in this embodiment, by configuring the ladder structure 132 including a plurality of ladder sub-sections spaced apart in the encapsulation region 3000, and by configuring the undercut opening 1320 to be defined on a lateral side of each of the ladder sub-sections, a number of cut off of the electrode layer 170 in the encapsulation region 3000 is effectively increased. Furthermore, moisture from intruding the device from an edge of the electrode layer 170 can be prevented better, the reliability of the display device is improved, and the service life of the display panel 1 is improved. Meanwhile, the second film layer 1322 includes a first sub-layer 1322A and a second sub-layer 1322B disposed in a stack on a side of the first film layer 1321 away from the substrate 10, the thickness of the second sub-layer 1322B is greater than a thickness of the first sub-layer 1322A, the first sub-layer 1322A is the metal film layer, and the second sub-layer 1322B is the organic film layer, thereby serving a protection effect to the first sub-layer 1322A and preventing poor phenomena such as collapse, etc. from appearing in the first sub-layer 1322A in manufacturing processes of the display panel 1 (e.g., performing opening design in the functional region 2000). Therefore, diffusion of water and oxygen from the encapsulation region 3000 to the display region 1000 and affecting reliability of the display device can be prevented.

Furthermore, the insulation layer 300 includes the second sub-layer 1322B. Wherein, the second insulation functional layer is located in the display region 1000, the second sub-layer 1322B and the second insulation functional layer have a same material and are disposed in a same layer, i.e., the second sub-layer 1322B and the second insulation functional layer can be manufactured in a same process. Therefore, manufacturing cost of the display panel 1 is reduced, while influence on the thickness of the display panel 1 is also minimized.

Preferably, the second sub-layer 1322B and the second planarization layer 140 are disposed in a same layer, a material of the second sub-layer 1322B is same as a material of the planarization layer 140, and a material of the second sub-layer 1322B includes an organic insulation material. It can be understood that in this embodiment, the material of the second film layer 1322 can be a metal material. In this embodiment, by configuring the material of the second sub-layer 1322B to be an organic insulation material, the second sub-layer 1322B disposed on the first sub-layer 1322A does not easily peel off due to the organic film layer and the metal film layer having good adhesive ability, thereby effectively improving protection effect of the second sub-layer 1322B to the first sub-layer 1322A.

Preferably, the thickness of the second sub-layer 1322B is greater than the thickness of the second planarization layer 140. It can be understood that the electrode layer 170 is located on a side of the second sub-layer 1322B away from the ladder structure 132. In this embodiment, by configuring a thickness of the second sub-layer 1322B to be greater than the thickness of the second planarization layer 140, the electrode layer 170 can be effectively cut off.

It should be noted that in this embodiment, the second sub-layer 1322B and the second planarization layer 140 is disposed in the same layer, and the material of the second sub-layer 1322B is same as the material of the planarization layer 140, which are only used for taking as an example. For example, in one embodiment, the second sub-layer 1322B and the pixel definition layer 150 are disposed in a same layer, and a material of the second sub-layer 1322B is same as a material of the pixel definition layer 150. In one embodiment, the second sub-layer 1322B and the spacer layer 160 are disposed in a same layer, a material of the second sub-layer 1322B is same as a material of the spacer layer 160. In this embodiment, a position and the material of the second sub-layer 1322B are not specifically limited.

In this embodiment, the display panel 1 further includes a plurality of channels 180 spaced apart and located in the encapsulation region 3000, and the channels 180 include via holes 181 penetrating through the first insulation functional layer. Wherein, orthogonal projections of the ladder sub-sections on the substrate 10 do not overlap with orthogonal projections of the channels 180 on the substrate 10. It can be understood that the via hole 181 of the channel 180 at least penetrates the third gate insulation layer 80 and the second interlayer insulation layer 100, thereby further preventing moisture and oxygen from intruding an interior of the display panel 1 and improving the product reliability.

Preferably, the encapsulation region 3000 includes a first encapsulation sub-region 3100, a second sub-region 3200, and a spacer region 3300 located between the first encapsulation sub-region 3100 and the second sub-region 3200. The first encapsulation region 3100 is close to the functional region 2000. The second encapsulation region 3200 is close to the display region 1000. The ladder structure 132 includes a plurality of first ladder sub-sections 132A disposed in the first encapsulation sub-region 3100, and a plurality of second ladder sub-sections 132B spaced apart in the second encapsulation sub-region 3200. Wherein, the channels 180 are located in the second encapsulation region 3200, and the orthogonal projections of the channels 180 on the substrate 10 do not overlap with orthogonal projections of the second ladder sub-sections 132B on the substrate 10. Preferably, the orthogonal projections of the second ladder sub-sections 132B on the substrate 10 are located between orthogonal projections of two adjacent channels 180 on the substrate 10.

It can be understood that, in this embodiment, by configuring the ladder structure 132 including the plurality of first ladder sub-sections 132A disposed in the first encapsulation sub-region 3100, and the plurality of second ladder sub-sections 132B spaced apart in the second encapsulation sub-region 3200, the electrode layer 170 is more effectively cut off in the encapsulation region 3000, preventing moisture from intruding the device from an edge of the electrode layer 170, and improving the reliability of the display device. Meanwhile, by disposing the channels 180 and the second ladder sub-sections 132B in the second encapsulation region 3200, the orthogonal projections of the second ladder sub-sections 132B on the substrate 10 are located between orthogonal projections of two adjacent channels 180 on the substrate 10, which further blocks moisture and oxygen from intruding into the display panel 1 to improve reliability and service life of products.

Wherein, the display panel 1 includes a bank 190 located in the spacer region 3300. The bank 190 is disposed to enclose the functional region 2000. The bank 190 includes the first planarization layer 120, the second planarization layer 140, the pixel definition layer 150, and the spacer layer 160 disposed in a stack. The bank 190 can prevent moisture and oxygen from intruding the interior of the display panel 1, and can reduce possibility of cracks extending toward the interior of the display panel 1 that may be formed when the opening is cut, thereby further improving encapsulation reliability.

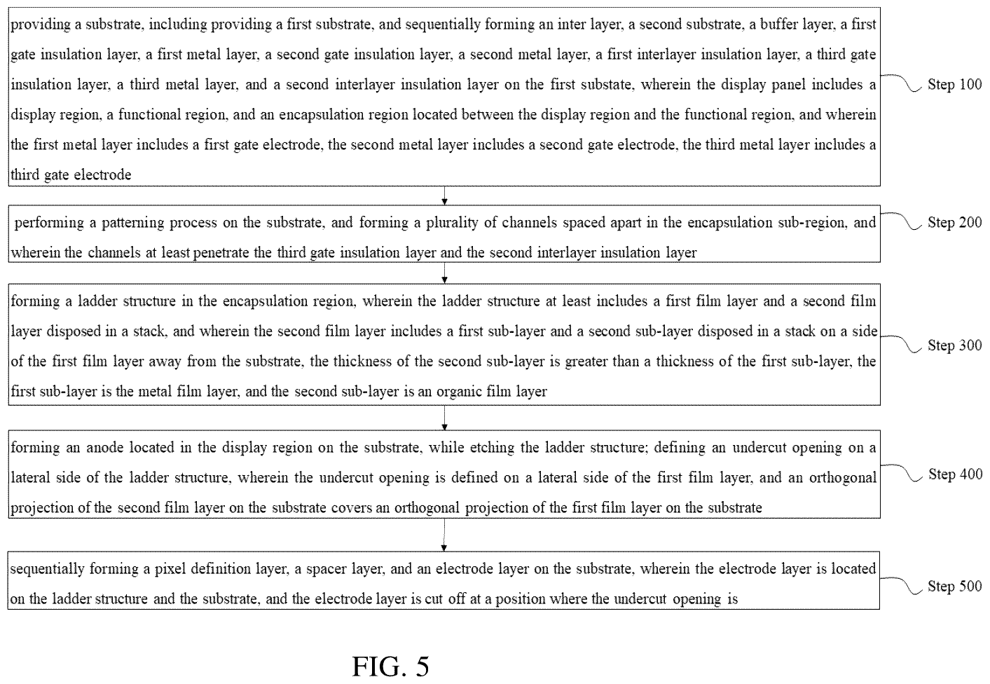

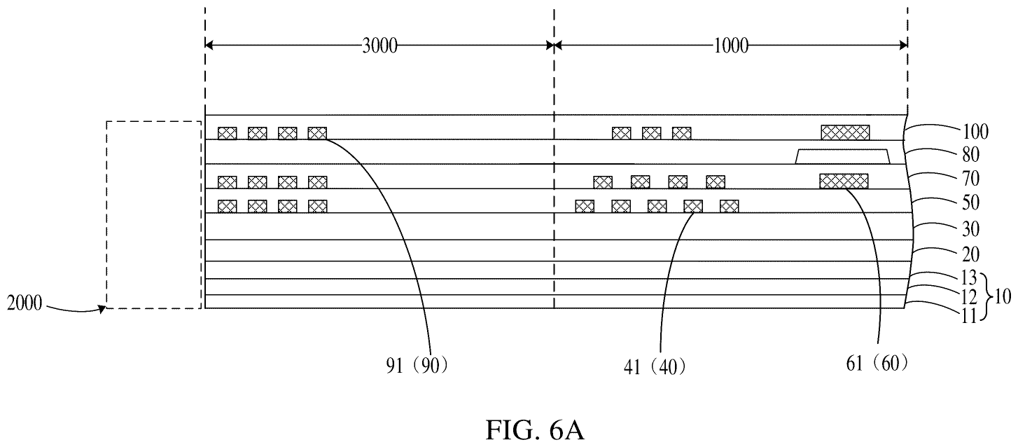

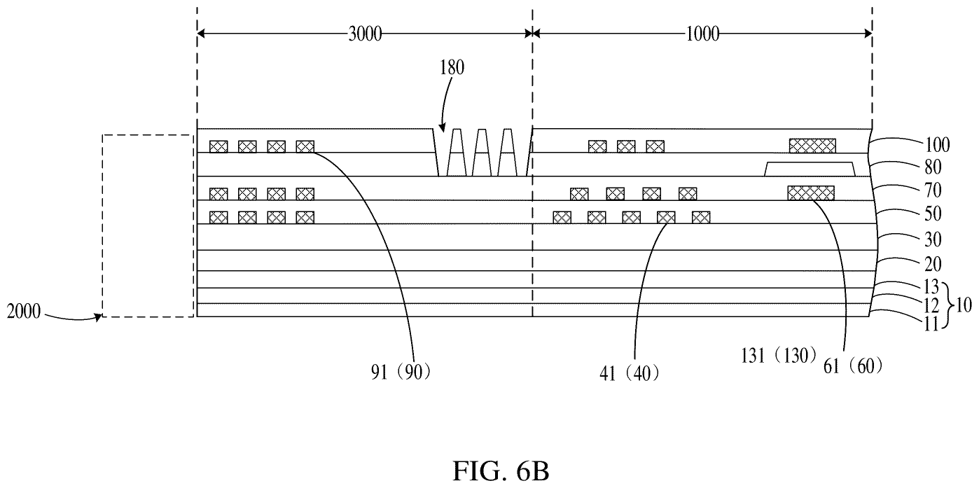

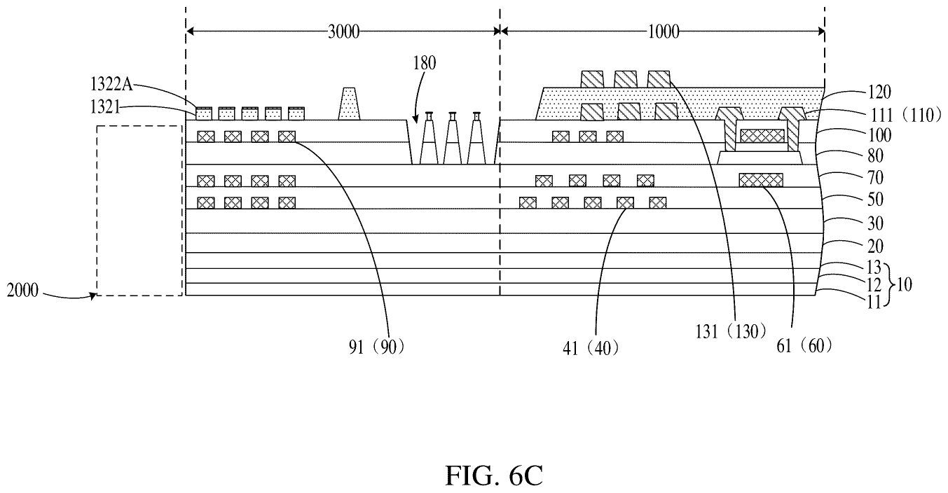

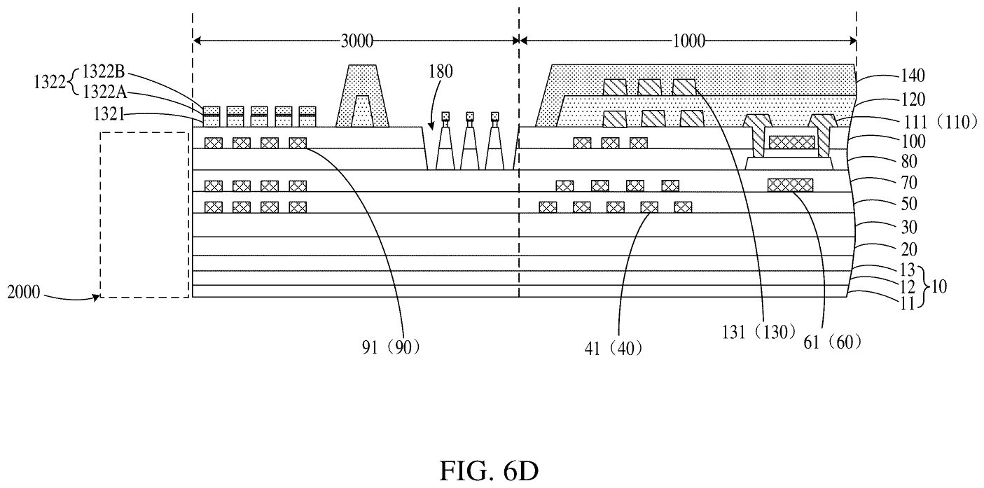

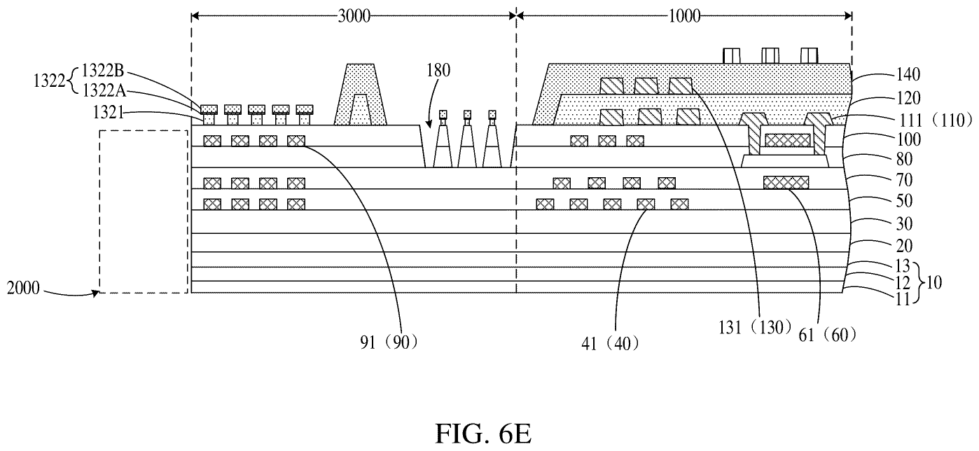

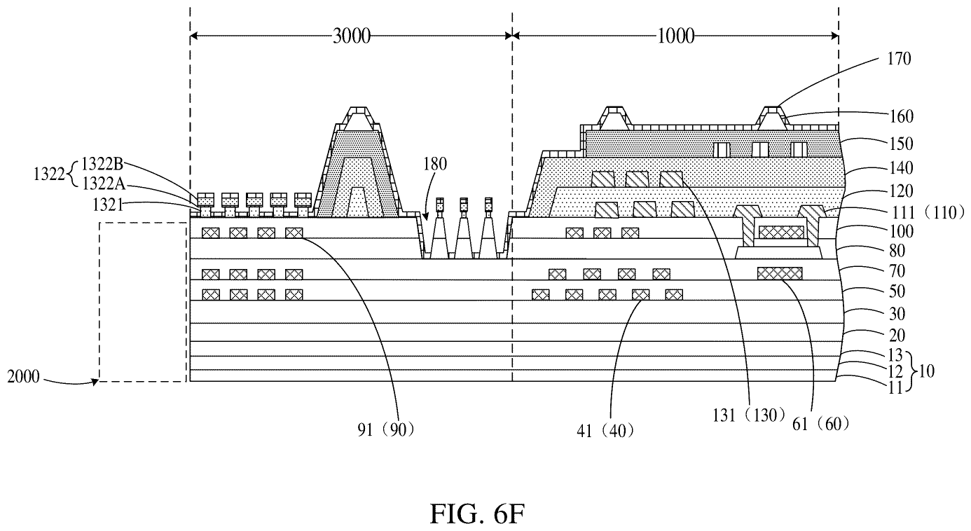

One embodiment of the present application further provides a manufacturing method of the display panel. Please combine FIG. 3, FIG. 4, FIG. 5, and FIG. 6A to FIG. 6F, the manufacturing method of the display panel includes following steps.

As illustrated in FIG. 6A, step 100: providing a substrate 10, including providing a first substrate 11, and sequentially forming an inter layer 12, a second substrate 13, a buffer layer 20, a first gate insulation layer 30, a first metal layer 40, a second gate insulation layer 50, a second metal layer 60, a first interlayer insulation layer 70, a third gate insulation layer 80, a third metal layer 90, and a second interlayer insulation layer 100 on the first substrate 11, wherein the display panel includes a display region 1000, a functional region 2000, and an encapsulation region 3000 located between the display region 1000 and the functional region 2000, and wherein the first metal layer 40 includes a first gate electrode 41, the second metal layer 60 includes a second gate electrode 61, the third metal layer 90 includes a third gate electrode 91.

As illustrated in FIG. 6B, step 200: performing a patterning process on the substrate 10, and forming a plurality of channels 180 spaced apart in the encapsulation sub-region 3000, and wherein the channels 180 at least penetrate the third gate insulation layer 80 and the second interlayer insulation layer 100.

Step 300: forming a ladder structure 132 in the encapsulation region 3000, wherein the ladder structure 132 at least includes a first film layer 1321 and a second film layer 1322 disposed in a stack, and wherein the second film layer 1322 includes a first sub-layer 1322A and a second sub-layer 1322B disposed in a stack on a side of the first film layer 1321 away from the substrate 10, the thickness of the second sub-layer 1322B is greater than a thickness of the first sub-layer 1322A, the first sub-layer 1322A is the metal film layer, and the second sub-layer 1322B is an organic film layer.

Specifically, in this embodiment, the step 300 includes following steps.

As illustrated in FIG. 6C, step S301: sequentially forming a fourth metal layer 110, a first planarization layer 120, and a fifth metal layer 130 on the second interlayer insulation layer 100, wherein the fourth metal layer 110 includes a first source-drain electrode 111 located in the display region 1000, and the fifth metal layer 130 includes a second source-drain electrode 131 located in the display region, and the first film layer 1321 and the first sub-layer 1322A located in the encapsulation region 3000.

As illustrated in FIG. 6D, step S302: forming a second insulation functional layer in the substrate 10, wherein the second insulation layer includes a second planarization layer 140 located in the display region 1000 and the second sub-layer 1322B located in the encapsulation layer 3000, and an orthogonal projection of the second sub-layer 1322B on the substrate 10 covers an orthogonal projection of the first sub-layer 1322A on the substrate 10.

As illustrated in FIG. 6E, step S400: forming an anode (not marked in the figure) located in the display region 1000 on the substrate 10, while etching the ladder structure 132; defining an undercut opening 1320 on a lateral side of the ladder structure 132, wherein the undercut opening 1320 is defined on a lateral side of the first film layer 1321, and an orthogonal projection of the second film layer 1322 on the substrate 10 covers an orthogonal projection of the first film layer 1321 on the substrate 10.

As illustrated in FIG. 6F, step 500: sequentially forming a pixel definition layer 150, a spacer layer 160, and an electrode layer 170 on the substrate 10, wherein the electrode layer 170 is located on the ladder structure 132 and the substrate 10, and the electrode layer 170 is cut off at a position where the undercut opening 1320 is.

This embodiment provides a display device, the display device includes the display panel of any aforesaid embodiment.

It can be understood that the display panel has been described in detail in the aforesaid embodiments, and the description will not be repeated here.

In specific applications, the display device can be a display screen of equipment of a smart phone, a tablet computer, a notebook computer, a smart bracelet, a smart watch, a smart glasses, a smart helmet, a desktop computer, a smart television, or a digital camera, etc., and can even be applied in electronic equipment with a flexible display screen.

In summary, the present application provides a display panel and a display device. The display panel includes a display region, a functional region, and an encapsulation region located between the display region and the functional region. The display panel includes: a substrate; a ladder structure disposed on the substrate and located in the encapsulation region, the ladder structure at least includes a first film layer and a second film layer disposed in a stack, wherein an undercut opening is defined on a lateral side of the first film layer, and an orthogonal projection of the second film layer on the substrate covers an orthogonal projection of the first film layer on the substrate; and an electrode layer disposed on the ladder structure and the substrate, wherein the electrode layer is cut off at a position where the undercut opening is. In the embodiments of the present application, by disposing the second film layer including a first sub-layer and a second sub-layer disposed in a stack on a side of the first film layer away from the substrate, by configuring a thickness of the second sub-layer to be greater than a thickness of the first sub-layer, by configuring the first sub-layer to be a metal film layer, and by configuring the second sub-layer to be an organic film layer, thereby serving a protection effect to the first sub-layer and preventing poor phenomena such as collapse, etc. from appearing in the first sub-layer in manufacturing processes of the display panel. These poor phenomena can lead to diffusion of water and oxygen from the encapsulation region to the display region and affecting reliability of the display device.

In summary, although the present application has disclosed the preferred embodiments as above, however the above-mentioned preferred embodiments are not to limit to the present application. A person skilled in the art can make any change and modification, therefore the scope of protection of the present application is subject to the scope defined by the claims.

What is claimed is:

1. A display panel, comprising a display region, a functional region, and an encapsulation region located between the display region and the functional region;
wherein the display panel comprises:
a substrate;
a ladder structure disposed on the substrate and located in the encapsulation region, wherein an undercut opening is defined on a lateral side of the ladder structure, the ladder structure at least comprises a first film layer and a second film layer disposed in a stack, the undercut opening is defined on a lateral side of the first film layer, and
an orthogonal projection of the second film layer on the substrate covers an orthogonal projection of the first film layer on the substrate; and
an electrode layer disposed on the ladder structure and the substrate, wherein the electrode layer is cut off at a position where the undercut opening is; and
wherein the second film layer comprises a first sub-layer and a second sub-layer disposed in a stack on a side of the first film layer away from the substrate, a thickness of the second sub-layer is greater than a thickness of the first sub-layer, the first sub-layer is a metal film layer, and the second sub-layer is an organic film layer.

2. The display panel as claimed in claim 1, wherein the display panel comprises a first insulation functional layer located between the substrate and the ladder structure;
the ladder structure comprises a plurality of ladder sub-sections spaced apart in the encapsulation region, the undercut opening is defined on a lateral side of each of the ladder sub-sections; and
wherein the electrode layer comprises a first electrode layer located on a plurality of the ladder sub-sections, and a second electrode layer located on the first insulation functional layer.

3. The display panel as claimed in claim 2, wherein the display panel comprises a plurality of channels spaced apart and located in the encapsulation region, and the channels comprise via holes penetrating through the first insulation functional layer; and
wherein orthogonal projections of the ladder sub-sections on the substrate do not overlap with orthogonal projections of the channels on the substrate.

4. The display panel as claimed in claim 3, wherein the encapsulation region comprises a first encapsulation sub-region, a second sub-region, and a spacer region located between the first encapsulation sub-region and the second sub-region,
the first encapsulation region is close to the functional region, and the second encapsulation region is close to the display region;
the ladder structure comprises a plurality of first ladder sub-sections disposed in the first encapsulation sub-region, and a plurality of second ladder sub-sections spaced apart in the second encapsulation sub-region;
the channels are located in the second encapsulation region, and the orthogonal projections of the channels on the substrate do not overlap with orthogonal projections of the second ladder sub-sections on the substrate.

5. The display panel as claimed in claim 4, wherein the orthogonal projections of the second ladder sub-sections on the substrate are located between orthogonal projections of two adjacent channels on the substrate.

6. The display panel as claimed in claim 1, wherein the display panel comprises a thin film transistor layer disposed on the substrate and an insulation layer disposed on the thin film transistor layer, and the insulation layer comprises a second insulation functional layer located in the display region and the second sub-layer located in the encapsulation region.

7. The display panel as claimed in claim 6, wherein the second insulation functional layer comprises a planarization layer located in the display region and disposed on the thin film transistor layer, and a material of the second sub-layer is same as a material of the planarization layer.

8. The display panel as claimed in claim 6, wherein a thickness of the second sub-layer is greater than or equal to a thickness of the planarization layer.

9. The display panel as claimed in claim 6, wherein the thin film transistor layer comprises a metal layer located between the substrate and the insulation layer, and the metal layer comprises the ladder structure;
wherein the ladder structure comprises a third film layer, the first film layer, and the second film layer disposed in a stack; and wherein a material of the third film layer, a material of the first film layer, and a material of the first film layer are metal metals, and a material of the second sub-layer is an organic insulation material.

10. The display panel as claimed in claim 9, wherein an orthogonal projection of the third film layer on the substrate overlaps with an orthogonal projection of the second film layer on the substrate.

11. A display device, wherein the display device comprises a display panel, and the display panel comprises:
a display region, a functional region, and an encapsulation region located between the display region and the functional region;
wherein the display panel comprises:
a substrate;
a ladder structure disposed on the substrate and located in the encapsulation region, wherein an undercut opening is defined on a lateral side of the ladder structure, the ladder structure at least comprises a first film layer and a second film layer disposed in a stack, the undercut opening is defined on a lateral side of the first film layer, and an orthogonal projection of the second film layer on the substrate covers an orthogonal projection of the first film layer on the substrate; and
an electrode layer disposed on the ladder structure and the substrate, wherein the electrode layer is cut off at a position where the undercut opening is; and
wherein the second film layer comprises a first sub-layer and a second sub-layer disposed in a stack on a side of the first film layer away from the substrate, a thickness of the second sub-layer is greater than a thickness of the first sub-layer, the first sub-layer is a metal film layer, and the second sub-layer is an organic film layer.

12. The display device as claimed in claim 11, wherein the display panel comprises a first insulation functional layer located between the substrate and the ladder structure;
the ladder structure comprises a plurality of ladder sub-sections spaced apart in the encapsulation region, the undercut opening is defined on a lateral side of each of the ladder sub-sections; and
wherein the electrode layer comprises a first electrode layer located on a plurality of the ladder sub-sections, and a second electrode layer located on the first insulation functional layer.

13. The display device as claimed in claim 12, wherein the display panel comprises a plurality of channels spaced apart and located in the encapsulation region, and the channels comprise via holes penetrating through the first insulation functional layer; and
wherein orthogonal projections of the ladder sub-sections on the substrate do not overlap with orthogonal projections of the channels on the substrate.

14. The display device as claimed in claim 13, wherein the encapsulation region comprises a first encapsulation sub-region, a second sub-region, and a spacer region located between the first encapsulation sub-region and the second sub-region, the first encapsulation region is close to the functional region, and the second encapsulation region is close to the display region;
the ladder structure comprises a plurality of first ladder sub-sections disposed in the first encapsulation sub-region, and a plurality of second ladder sub-sections spaced apart in the second encapsulation sub-region;
the channels are located in the second encapsulation region, and the orthogonal projections of the channels on the substrate do not overlap with orthogonal projections of the second ladder sub-sections on the substrate.

15. The display device as claimed in claim 14, wherein the orthogonal projections of the second ladder sub-sections on the substrate are located between orthogonal projections of two adjacent channels on the substrate.

16. The display device as claimed in claim 11, wherein the display panel comprises a thin film transistor layer disposed on the substrate and an insulation layer disposed on the thin film transistor layer, and the insulation layer comprises a second insulation functional layer located in the display region and the second sub-layer located in the encapsulation region.

17. The display device as claimed in claim 16, wherein the second insulation functional layer comprises a planarization layer located in the display region and disposed on the thin film transistor layer, and a material of the second sub-layer is same as a material of the planarization layer.

18. The display device as claimed in claim 16, wherein a thickness of the second sub-layer is greater than or equal to a thickness of the planarization layer.

19. The display device as claimed in claim 16, wherein the thin film transistor layer comprises a metal layer located between the substrate and the insulation layer, and the metal layer comprises the ladder structure;
wherein the ladder structure comprises a third film layer, the first film layer, and the second film layer disposed in a stack; and wherein a material of the third film layer, a material of the first film layer, and a material of the first film layer are metal metals, and a material of the second sub-layer is an organic insulation material.

20. The display device as claimed in claim 19, wherein an orthogonal projection of the third film layer on the substrate overlaps with an orthogonal projection of the second film layer on the substrate.
